(19) United States
(12) Patent Application Publication
(10) Pub. No.: US 2004/0115948 A1
(43) Pub. Date: Jun. 17, 2004

(54) Method for fabricating on stack structures in a semiconductor device

(75) Inventors: Yung Hsien Wu, Hsinchu (TW); Jer Lee, Hsinchu (TW)

Correspondence Address: Finnegan, Henderson, Farabow,, Garrett & Dunner, L.L.P., 1300 I Street, N.W., Washington, DC, 20005-3315, US

(73) Assignee: ProMOS Technologies, Inc.

(21) Appl. No.: 10/317,039

(22) Filed: Dec. 12, 2002

(51) Int. Cl. H01L 21/302

(52) U.S. Cl. 438/724

(57) ABSTRACT

A method for manufacturing a semiconductor device that includes providing a first layer, cleaning the first layer, growing an oxide layer over the first layer at a reduced pressure from an atmospheric pressure, and depositing a nitride layer over the oxide layer, wherein the growing of the oxide layer and depositing of the nitride layer are performed in the same furnace.

### FIELD OF THE INVENTION

The present invention relates generally to a method for fabricating a semiconductor device and, more particularly, to a method for fabricating an ON dielectric stack for a memory device.

### BACKGROUND OF THE INVENTION

Memory devices such as a dynamic random access memory (DRAM) have been widely employed in integrated circuit (IC) devices. A memory cell used in DRAM IC devices generally includes a read transistor and a storage capacitor to store data. Because of the inherency of the DRAM design, the capacitor should have a high capacitance to keep its data storage time as long as possible. As a result, a dielectric having high dielectric value (k) for keeping cell capacitance in high-density memory devices is greatly desired. The IC industry has experimented with dielectric materials, such as Ta₂O₅ and Al₂O₃.

Generally, a conventional stacked dielectric configuration is commonly favored in high-storage density applications. Oxide/nitride (ON) dielectric stacks have been utilized both as insulators and storage dielectrics. However, the bottom oxide layer, generally grown under atmospheric pressures, cannot be scaled for high-density applications, and therefore imposes a limitation on the maximum attainable capacitance. As a result, nitride/oxide (NO) and nitride/oxide/nitride (NON) dielectric stacks, with the bottom layer being the more scalable nitride layer, have largely replaced the ON dielectric stack. However, both suffer from high leakage current and require complicated manufacture processes. In addition, nitride/silicon interface is not as good as the oxide/silicon interface. Specifically, the interface trap density for the nitride/silicon interface is about 10¹⁰ cm⁻², which is half to one order magnitude higher than the interface trap density associated with the oxide/silicon interface.

As an alternate embodiment, oxide/nitride/oxide (ONO) composite dielectric, which has a higher breakdown voltage than a single oxide film, may be used in place of the ON stacks as an insulator between a substrate and a gate. Nevertheless, the enhanced capacitance of the DRAM cells due to use of the ONO dielectric leads to higher leakage current and comes at a price of complicated processing steps. This results in a higher manufacturing cost and lower device yield.

In view of the abovementioned problems, there is a continued need for dielectric layers of improved capacitance and reduced cost.

### SUMMARY OF THE INVENTION

In accordance with the invention, there is provided a method for manufacturing a semiconductor device that includes providing a first layer, cleaning the first layer, growing an oxide layer over the first layer at a reduced pressure from an atmospheric pressure, and depositing a nitride layer over the oxide layer, wherein the growing of the oxide layer and depositing of the nitride layer are performed in the same furnace.

Also in accordance with the invention, there is provided a method of manufacturing a semiconductor device that includes providing a first layer, growing an oxide layer over the first layer at a reduced pressure from an atmospheric pressure, annealing the oxide layer formed over the first layer, depositing a nitride layer over the annealed oxide layer, and oxidizing the annealed oxide layer and the nitride layer deposited over the annealed oxide layer.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawing, which is incorporated in and constitutes a part of this specification, illustrate one embodiment of the invention and together with the description, serve to explain the principles of the invention.

### BRIEF DESCRIPTION OF THE DRAWINGS

FIG. 1 is a cross-sectional view of the structure formed with an embodiment of the method of the present invention.

### DESCRIPTION OF THE EMBODIMENTS

Reference will now be made in detail to the present embodiments of the invention, examples of which are illustrated in the accompanying drawings. Wherever possible, the same reference numbers will be used throughout the drawings to refer to the same or like parts.

The method of the present invention provides an improved oxide/nitride (ON) stack. The bottom oxide layer is provided through a low-pressure oxidation process. Because oxide growth under low-pressure conditions may be readily controlled, the oxide layer formed with the method of the present invention is more scalable than oxides formed with traditional atmospheric oxidation processes. The upper nitride layer is then provided through in-situ deposition. In addition, the in-situ deposition may be performed in the same furnace in which the oxidation step is performed to further simplify and lower the cost of the manufacturing process.

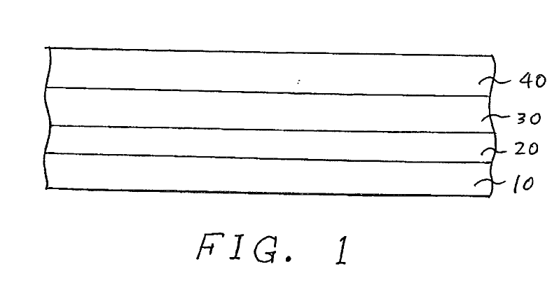

FIG. 1 is a cross-sectional view of the structure formed with the method of the present invention. Referring to FIG. 1, the method of the present invention begins with cleaning a first layer 10 by removing any native oxide that may have been grown over first layer 10. This cleaning step may be performed with a hydrogen-flouride (HF) solution. In one embodiment, first layer 10 may be a silicon substrate. In another embodiment, first layer 10 is a silicon layer.

The oxide layer of the ON stack is then grown over first layer 10. Specifically, a first oxide layer (SiO₂) 20 is grown over first layer 10 in oxygen ambient. The growth of first oxide layer 20 is performed at a reduced pressure of about 500 torr or less. The oxidation process, or the rate of oxidation, is readily controllable at a reduced pressure from the atmospheric pressure (1 atm or 760 torr). In one embodiment, the process for growing first oxide layer 20 is performed at a temperature of about 900° C. and under a pressure of about 0.5 torr to provide first oxide layer 20 having a thickness of about 15 Å.

An optional annealing step may then follow to form a nitrogen-rich layer at the interface between first layer 10 and first oxide layer 20. Under the same processing conditions for the formation of oxide layer 20, an anneal step is performed with nitrous oxide (N₂O). The annealing step forms an oxynitride layer that improves the quality of first oxide layer 20 and reduces electron trapping by replacing strained silicon-oxygen bonds with silicon-nitrogen bonds. The anneal step improves the reliability of the stacked structure. Specifically, together with a thinner nitride layer, the optional annealing step provides first oxide layer 20 having higher effective dielectric constant.

A nitride layer 30 is then deposited over first oxide layer 20. The deposition process is achieved through a chemical reaction between dichlorosilane (SiH₂Cl₂) and ammonia (NH₃) using conventional chemical vapor deposition (CVD) techniques. In one embodiment, the deposition process is performed at a temperature of about 700° C. and under a pressure of about 0.25 torr to provide nitride layer 30 having a thickness of about 35 Å.

In one embodiment, the deposition process of nitride layer 30 and oxidation process of first oxide layer 20 are performed in the same furnace. In one embodiment, the furnace is a low-pressure CVD (LPCVD) furnace. This embodiment further simplifies the method of the present invention, which in turn reduces the manufacturing cost.

Referring again to FIG. 1, a second oxide layer 40 is formed over nitride layer 30 by an in-situ oxidation process in N₂O ambient. In one embodiment, formation of second oxide layer 40 is performed with a steep increase in temperature from about 700° C. up to 900° C. The formation of second oxide layer 40 decreases defects, such as pinholes, in nitride layer 30. As a result, reduction of leakage current can be achieved. The resulting stack structure, with the optional annealing step that provides a nitrogen-rich layer (oxynitride layer), includes a silicon layer, an oxynitride layer, a nitride layer, and an oxide layer.

Furthermore, each of the steps for the formation of the ON stack of the present invention may be performed in the same furnace, such as a LPCVD furnace. Specifically, the oxidation step for the formation of first oxide layer 20, annealing, deposition of nitride layer 30, and re-oxidation step may all be performed in the same furnace. The method of the present invention is therefore able to reduce the manufacturing cost. In addition, the method of the present invention therefore improves the electrical performance of the resulting memory device, such as a DRAM IC device with increased capacitance, reduced leakage current, and lower breakdown voltage can be obtained in accordance with the method of the present invention. The method of the present invention may also be integrated into any conventional processes to significantly simplify the manufacturing process.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of manufacturing a semiconductor device, comprising:
providing a first layer;
cleaning the first layer;
growing an oxide layer over the first layer at a reduced pressure from an atmospheric pressure; and
depositing a nitride layer over the oxide layer,
wherein the growing of the oxide layer and depositing of the nitride layer are performed in the same furnace.

2. The method of claim 1, further comprising forming a second oxide layer over the nitride layer by an oxidation process.

3. The method of claim 1, further comprising forming a nitrogen-rich layer at an interface between the first layer and the oxide layer by annealing the oxide layer with nitrous oxide N₂O.

4. The method of claim 1, wherein growth of the oxide layer includes an oxidation step performed under a pressure of about 0.5 torr.

5. The method of claim 1, wherein growth of the oxide layer includes an oxidation step performed at a temperature of about 900° C.

6. The method of claim 3, wherein the nitrogen-rich layer is formed at a temperature of about 900° C. and a pressure of about 0.5 torr.

7. The method of claim 1, wherein depositing the nitride layer includes reacting dichlorosilane and ammonia.

8. The method of claim 1, wherein the nitride layer is deposited at a temperature of about 700° C.

9. The method of claim 1, wherein the nitride layer is deposited under a pressure of about 0.25 torr.

10. The method of claim 3, wherein annealing is performed in nitrous oxide ambient.

11. A method of manufacturing a semiconductor device, comprising:
providing a first layer;
growing an oxide layer over the first layer at a reduced pressure from an atmospheric pressure;
annealing the oxide layer formed over the first layer;
depositing a nitride layer over the annealed oxide layer; and
oxidizing the annealed oxide layer and the nitride layer deposited over the annealed oxide layer.

12. The method of claim 11, wherein the steps of growing an oxide layer, annealing the oxide layer, depositing a nitride layer, and oxidizing the annealed oxide layer and the nitride layer are performed in the same furnace.

13. The method of claim 11, further comprising cleaning the first layer before growing the oxide layer.

14. The method of claim 11, wherein growth of the oxide layer includes an oxidation step performed under a pressure of about 0.5 torr.

15. The method of claim 11, wherein growth of the oxide layer includes an oxidation step performed at a temperature of about 900° C.

16. The method of claim 11, wherein the annealing step is formed at a temperature of about 900° C. and a pressure of about 0.5 torr.

17. The method of claim 11, wherein depositing the nitride layer includes reacting dichlorosilane and ammonia.

18. The method of claim 11, wherein the nitride layer is deposited at a temperature of about 700° C.

19. The method of claim 11, wherein the nitride layer is deposited under a pressure of about 0.25 torr.

20. The method of claim 11, wherein the annealing is performed in nitrous oxide ambient.
